(19) United States
(12) Patent Application Publication
(10) Pub. No.: US 2025/0273427 A1
(43) Pub. Date: Aug. 28, 2025

(54) Isolation Valve for Implant Productivity Enhancement

(71) Applicant: Applied Materials, Inc., Santa Clara, CA (US)

(72) Inventors: Gregory Edward Stratoti, Sandown, NH (US); Timothy J. Rammel, Brookline, NH (US); Bon-Woong Koo, Andover, MA (US); Tseh-Jen Hsieh, Rowley, MA (US)

(21) Appl. No.: 18/888,928

(22) Filed: Sep. 18, 2024

Related U.S. Application Data
(60) Provisional application No. 63/557,867, filed on Feb. 26, 2024.

(51) Int. Cl. H01J 37/317; H01J 37/08

(52) U.S. Cl. CPC H01J 37/3171; H01J 37/08; H01J 2237/04735; H01J 2237/04756

(57) ABSTRACT

An isolation valve for use in an ion implantation system is disclosed. The isolation valve is disposed between the process chamber, which houses the workpiece to be implanted, and the components located immediately upstream from the process chamber. This isolation valve may be closed to allow preventative maintenance to be performed on the process chamber without venting the rest of the ion implantation system. This may reduce particles and other material from traveling upstream from the process chamber during a preventive maintenance operation. This enhancement may reduce the frequency that the rest of the system undergoes preventative maintenance.

This application claims priority of U.S. Provisional Patent Application Ser. No. 63/557,867, filed Feb. 26, 2024, the disclosure of which is incorporated herein by reference in its entirety.

### FIELD

Embodiments of the present disclosure relate to an ion implantation system that includes an isolation valve disposed between the process chamber and the components upstream therefrom.

### BACKGROUND

Semiconductor workpieces, such as silicon wafers, silicon oxide wafers, gallium nitride wafers and others, may be implanted with impurities to create semiconductor devices, such as transistors. In operation, an ion source is used to generate an ion beam. That ion beam travels through one or more components which shape and direct the ion beam toward the workpiece.

The workpiece is disposed on a platen, which is located within a process chamber. Load locks and robots are typically used to move workpieces into and from the process chamber so that the workpieces may be processed by the ion beam. The entire ion implantation system resides in a near vacuum environment.

Periodically, the ion implantation system may be subject to preventative maintenance. To perform this maintenance, the ion implantation system is vented to atmosphere to allow the various components to be inspected, serviced and cleaned.

However, in certain embodiments, the process chamber may preferably be cleaned more frequently, as sputtered material, such as silicon, may become deposited on the walls of the process chamber during the implantation process.

Consequently, it would be beneficial if there was a system and method that isolated the process chamber from the rest of the ion implantation system to allow localized preventative maintenance.

### SUMMARY

An isolation valve for use in an ion implantation system is disclosed. The isolation valve is disposed between the process chamber, which houses the workpiece to be implanted, and the components located immediately upstream from the process chamber. This isolation valve may be closed to allow preventative maintenance to be performed on the process chamber without venting the rest of the ion implantation system. This may reduce particles and other material from traveling upstream from the process chamber during a preventive maintenance operation. This enhancement may reduce the frequency that the rest of the system undergoes preventative maintenance.

According to one embodiment, an ion implantation system is disclosed. The ion implantation system comprises an ion source to generate an ion beam; one or more beamline components located downstream from the ion source to guide the ion beam toward a workpiece; a process chamber, housing a platen; and an isolation valve disposed between the process chamber and a component of the one or more beamline components located immediately upstream from the process chamber. In some embodiments, the component located immediately upstream from the process comprises an acceleration/deceleration stage. In certain embodiments, the acceleration/deceleration stage is an electrostatic filter comprising a plurality of biased rods. In certain embodiments, the isolation valve does not contact any of the plurality of biased rods. In some embodiments, the isolation valve comprises a body and a movable plate. In certain embodiments, the movable plate descends from a location above the ion beam to isolate the process chamber. In certain embodiments, the movable plate moves upward from a location below the ion beam to isolate the process chamber. In certain embodiments, the movable plate travels along a path parallel to a front wall of the process chamber.

According to another embodiment, an ion implantation system is disclosed. The ion implantation system comprises an ion source to generate an ion beam; one or more beamline components located downstream from the ion source to guide the ion beam toward a workpiece; a process chamber, housing a platen; and an isolation valve disposed between the process chamber and a component of the one or more beamline components located immediately upstream from the process chamber, wherein the isolation valve comprises a body and a movable plate and the movable plate travels along a path that is not parallel to a front wall of the process chamber. In some embodiments, the movable plate moves upward from a location below the ion beam to isolate the process chamber. In certain embodiments, as the movable plate moves upward, the movable plate draws closer to the process chamber. In some embodiments, the movable plate moves downward from a location above the ion beam to isolate the process chamber. In certain embodiments, as the movable plate moves downward, the movable plate draws closer to the process chamber. In some embodiments, the component located immediately upstream from the process chamber comprises an acceleration/deceleration stage. In certain embodiments, the acceleration/deceleration stage is an electrostatic filter comprising a plurality of biased rods, and wherein the isolation valve does not contact any of the plurality of biased rods.

According to another embodiment, an ion implantation system is disclosed. The ion implantation system comprises an ion source to generate an ion beam; one or more beamline components located downstream from the ion source to guide the ion beam toward a workpiece; a process chamber, housing a platen; and an isolation valve disposed between the process chamber and a component of the one or more beamline components located immediately upstream from the process chamber, wherein the isolation valve comprises a body and a movable plate, wherein the movable plate descends from a location above the ion beam to isolate the process chamber. In some embodiments, the movable plate travels along a path parallel to a front wall of the process chamber. In some embodiments, the movable plate travels along a path that is not parallel to a front wall of the process chamber. In some embodiments, the component located immediately upstream from the process chamber comprises an acceleration/deceleration stage. In certain embodiments, the acceleration/deceleration stage is an electrostatic filter comprising a plurality of biased rods, and wherein the isolation valve does not contact any of the plurality of biased rods.

### BRIEF DESCRIPTION OF THE FIGURES

For a understanding of the present disclosure, reference is made to the accompanying drawings, which are incorporated herein by reference and in which:

FIG. 1 shows an ion implantation system that may utilize an isolation valve;

FIGS. 2A-2B show an isolation valve in the open and closed positions, respectively, according to one embodiment;

FIGS. 3A-3B show the isolation valve disposed before the process chamber in the open and closed positions, respectively, according to a first embodiment;

FIGS. 4A-4B show the isolation valve disposed before the process chamber in the open and closed positions, respectively, according to a second embodiment;

FIGS. 5A-5B show the isolation valve disposed before the process chamber in the open and closed positions, respectively, according to a third embodiment;

FIGS. 6A-6B show the isolation valve disposed before the process chamber in the open and closed positions, respectively, according to a fourth embodiment;

FIGS. 7A-7B show the isolation valve disposed before the process chamber in the open and closed positions, respectively, according to a fifth embodiment; and

FIGS. 8A-8B show the isolation valve disposed before the process chamber in the open and closed positions, respectively, according to a sixth embodiment.

### DETAILED DESCRIPTION

As described above, in certain systems, it may be desirable to clean the process chamber without venting the rest of the ion implantation system to atmosphere. The present system allows for this capability.

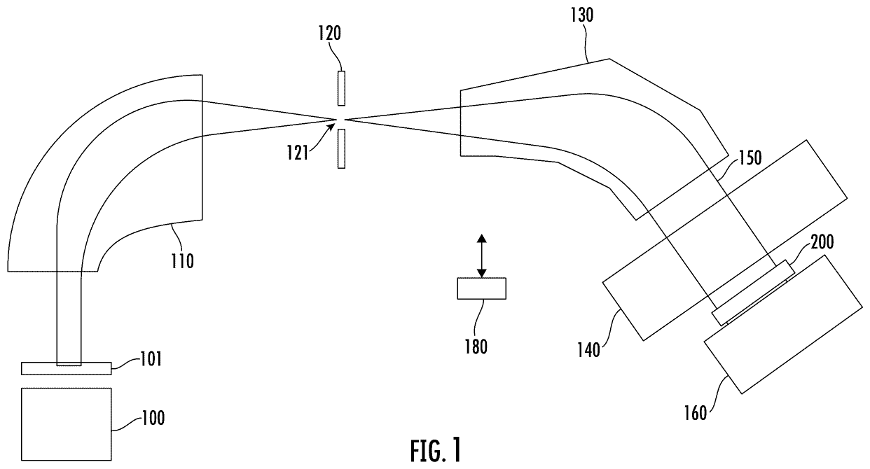

FIG. 1 shows an ion implantation system that may be used with the isolation valve. An ion source 100 is used to generate an ion beam 150. The ion source 100 may be a an indirectly heated cathode (IHC) ion source. Alternatively, the ion source 100 may be a capacitively coupled plasma source, an inductively coupled plasma source, a Bernas source or another source. Thus, the type of ion source is not limited by this disclosure. Disposed outside and proximate the extraction aperture of the ion source 100 is the extraction optics 101, which may comprise one or more electrodes.

Located downstream from the extraction optics 101 is a mass analyzer 110. The mass analyzer 110 uses magnetic fields to guide the path of the extracted ion beam. The magnetic fields affect the flight path of ions according to their mass and charge. A mass resolving device 120 that has a resolving aperture 121 is disposed at the output, or distal end, of the mass analyzer 110. By proper selection of the magnetic fields, only those ions in the ion beam 150 that have a selected mass and charge will be directed through the resolving aperture 121. Other ions will strike the mass resolving device 120 or a wall of the mass analyzer 110 and will not travel any further in the system.

A collimator 130 may be disposed downstream from the mass resolving device 120. The collimator 130 accepts the ions from the ion beam 150 that pass through the resolving aperture 121 and creates an ion beam formed of a plurality of parallel or nearly parallel beamlets. The output, or distal end, of the mass analyzer 110 and the input, or proximal end, of the collimator 130 may be a fixed distance apart. The mass resolving device 120 is disposed in the space between these two components.

Located downstream from the collimator 130 may be an acceleration/deceleration stage 140. The acceleration/deceleration stage 140 is a beam-line lens component configured to independently control deflection, deceleration, and focus of the ion beam. For example, the acceleration/deceleration stage 140 may be an electrostatic filter (EF). In certain embodiments, the electrostatic filter may comprise a plurality of rods, that are biased at different bias voltages. The location of these rods, as well as the bias voltages applied to them allow the travels through the ion beam to be manipulated as it acceleration/deceleration stage 140. The ion beam 150 that exits the acceleration/deceleration stage 140 enters the process chamber 160. In some embodiments, the pathway between the acceleration/deceleration stage 140 and the process chamber 160 may be referred to as a tunnel.

An isolation valve 200 disposed the is between acceleration/deceleration stage 140 and the process chamber 160, such as in the tunnel. When open, the process chamber 160 is in communication with the rest of the beam line components. However, when closed, the process chamber 160 is isolated from the rest of the beam line components, allowing the process chamber 160 to be vented and cleaned without affecting the rest of the beam line components. Alternatively, the isolation valve 200 also allows the rest of the beam line components may be vented while the process chamber 160 remains at vacuum conditions.

A controller 180 may be in communication with one or more of the power supplies in the system such that the voltage or current supplied by these power supplies may be monitored and/or modified. The controller 180 may include a processing unit, such as a microcontroller, a personal computer, a special purpose controller, or another suitable processing unit. The controller 180 may also include a non-transitory storage element, such as a semiconductor memory, a magnetic memory, or another suitable memory. This non-transitory storage element may contain instructions and other data that allows the controller 180 to perform the functions described herein.

While FIG. 1 shows one embodiment of an ion implantation system, it is understood that the isolation valve 200 may be used implantation in other ion systems. For example, in some embodiments, the last beam line component before the process chamber 160 may be different from the acceleration/deceleration stage 140 described above. Furthermore, in some embodiments, the ion beam may be a spot beam. Such an ion implantation system includes an ion source that creates a spot beam. This type of ion implantation system also includes a mass analyzer and a mass resolving device, as described above. In addition, a scanner, which may be electrostatic or another type is used to create a scanned ion beam. Specifically, after the mass resolving device, the spot beam may enter an electrostatic scanner, which is used to scan a spot beam in the width direction so as to form the scanned ion beam, which is in the form of a ribbon ion beam, having a width much larger than its height. The scanned ion beam may then pass through an angle corrector. The angle corrector is designed to deflect ions in the scanned ion beam to produce an ion beam having parallel ion trajectories, thus focusing the scanned ion beam. Specifically, the angle corrector is used to alter the diverging ion trajectory paths into substantially parallel paths of the ion beam 150. In some embodiments, the angle corrector may comprise magnetic pole pieces which are spaced apart to define a gap and a magnet coil which is coupled to a power supply. The scanned ion beam passes through the gap between the magnetic pole pieces and is deflected in accordance with the magnetic field in the gap. In other embodiments, the angle corrector may be an electrostatic lens, sometimes referred to as a parallelizing lens. The scanned beam exits the angle corrector and enters the process chamber. Thus, in this embodiment, the angle corrector may be the last beam line component before the process chamber. Thus, the disclosure is not limited to the ion implantation system shown in FIG. 1.

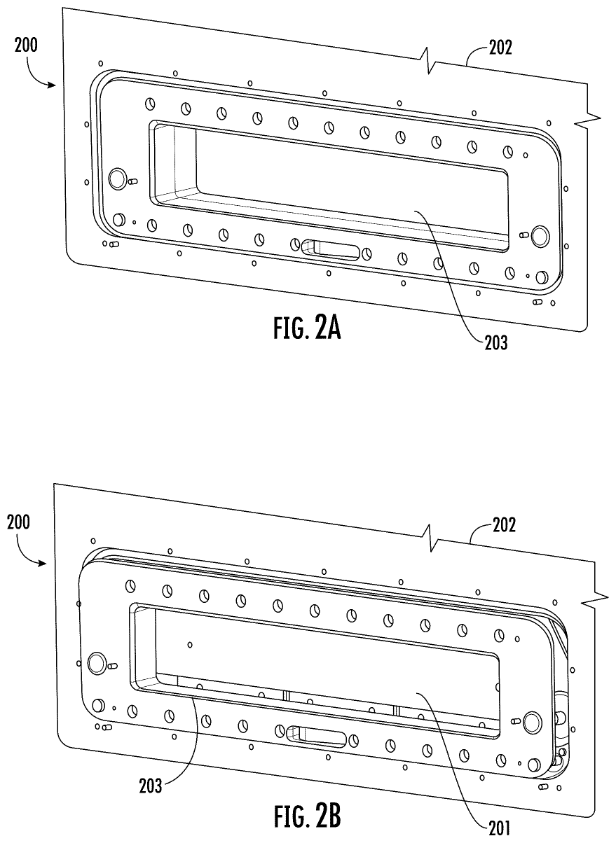

FIGS. 2A-2B show a front view of an isolation valve 200. The isolation valve 200 includes a body 202 having an opening 203. A movable plate 201 is adapted to move between the open position, shown in FIG. 2A and the closed position wherein the movable plate 201 covers the opening 203, as shown in FIG. 2B.

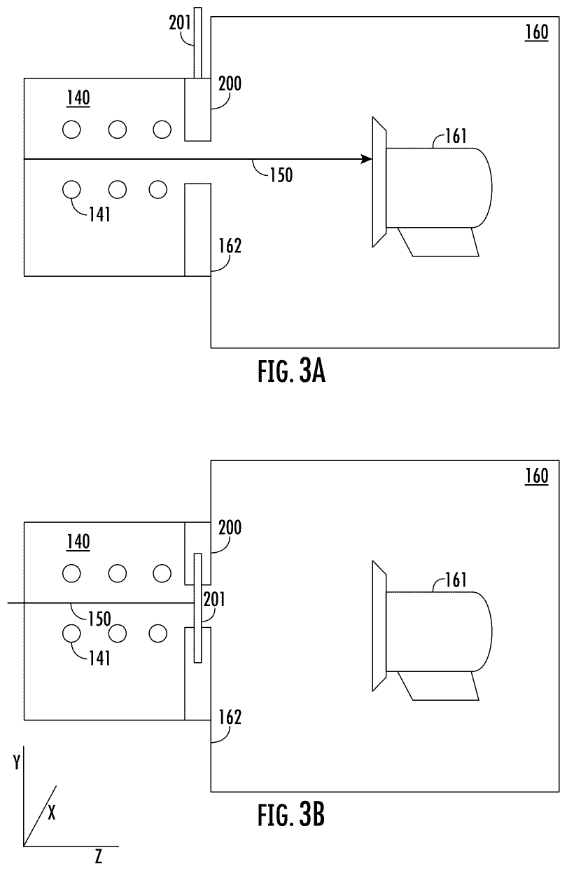

FIGS. 3A-3B show the isolation valve 200 according to a first embodiment. While FIG. 1 presented a top view of the ion implantation system, FIGS. 3A-3B are a side view of the acceleration/deceleration stage 140 and the process chamber 160. In this embodiment, the acceleration/deceleration stage 140 comprises a plurality of rods 141 that are biased so as to direct the ion beam 150 toward the platen 161, located within the process chamber 160. The rods serve to steer the ion beam 150.

In this embodiment, the isolation valve 200 is located between the process chamber 160 and the acceleration/deceleration stage 140. As described above, the isolation valve 200 comprises a movable plate 201 that has an open position (see FIG. 3A) and a closed position (see FIG. 3B). In this embodiment, the movable plate 201 moves in a direction that is parallel to the front wall 162 of the process chamber 160. Furthermore, the movable plate 201, descends from a position that is above the ion beam 150. In this disclosure, the term “above the ion beam” denotes that the movable plate is located above the ion beam in the vertical direction, wherein the vertical direction refers to the direction of gravity.

Thus, when in operation, as shown in FIG. 3A, the movable plate 201 is lifted above the ion beam 150 such that the ion beam 150 is able to pass through the opening 203 in the isolation valve 200. When in the closed position, as shown in FIG. 3B, the process chamber 160 is isolated from the acceleration/deceleration stage 140 and the rest of the beam line components.

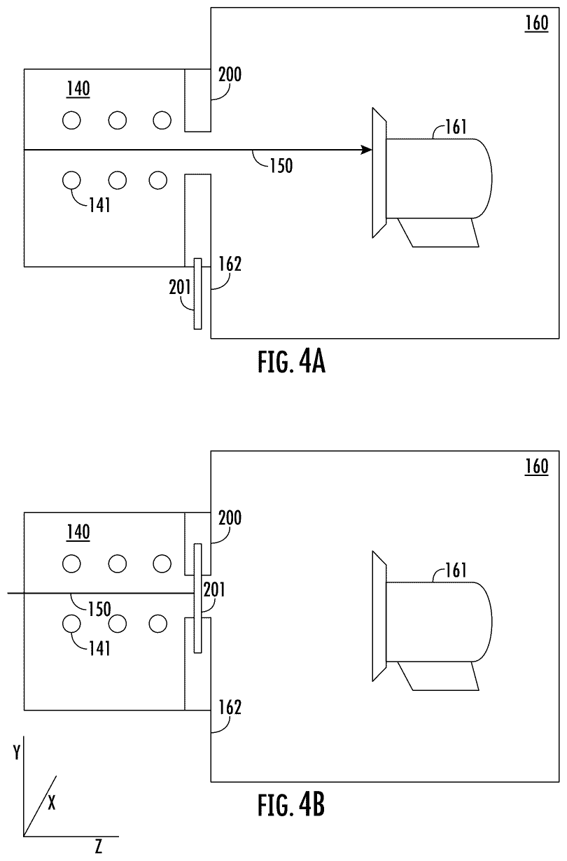

FIGS. 4A-4B show another embodiment that is similar to that shown in FIGS. 3A-3B. FIG. 4A shows an open position and FIG. 4B shows a closed position. However, in this embodiment, the movable plate 201 enters from the bottom of the body 202. Thus, to close the isolation valve 200, the movable plate 201 moves upward. Thus, in this embodiment, the movable plate 201 moves upward from a position that is below the ion beam 150. In this disclosure, the term “below the ion beam” denotes that the movable plate is located below the ion beam in the vertical direction, wherein the vertical direction refers to the direction of gravity.

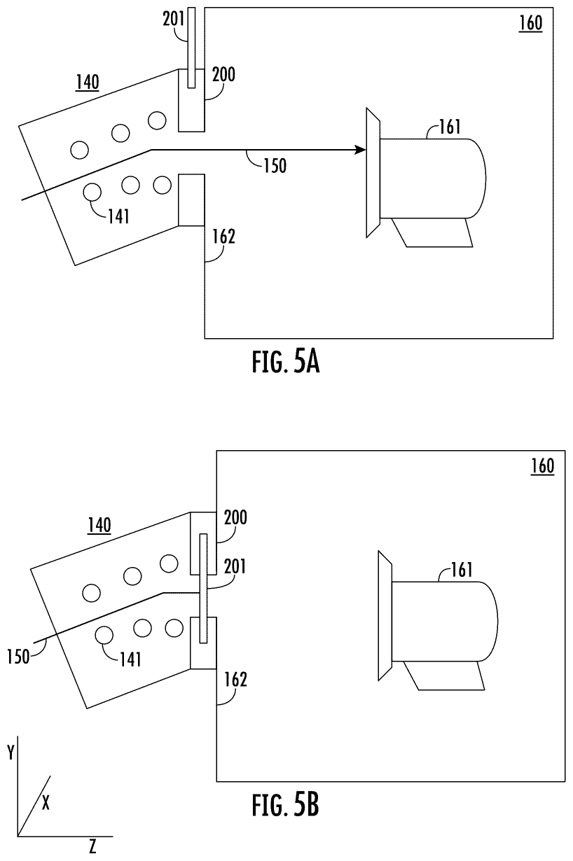

FIGS. 5A-5B show another embodiment. This embodiment is similar to that shown in FIGS. 3A-3B. FIG. 5A shows an open position and FIG. 5B shows a closed position. However, in this embodiment, some of the beam line components are positioned at a height that is lower than the entrance to the process chamber 160. Consequently, the ion beam 150 enters the acceleration/deceleration stage moving in an upward direction. As described above, the movable plate 201 moves in a direction that is parallel to the front wall 162 of the process chamber 160.

Furthermore, the movable plate 201 descends from a position that is above the ion beam 150.

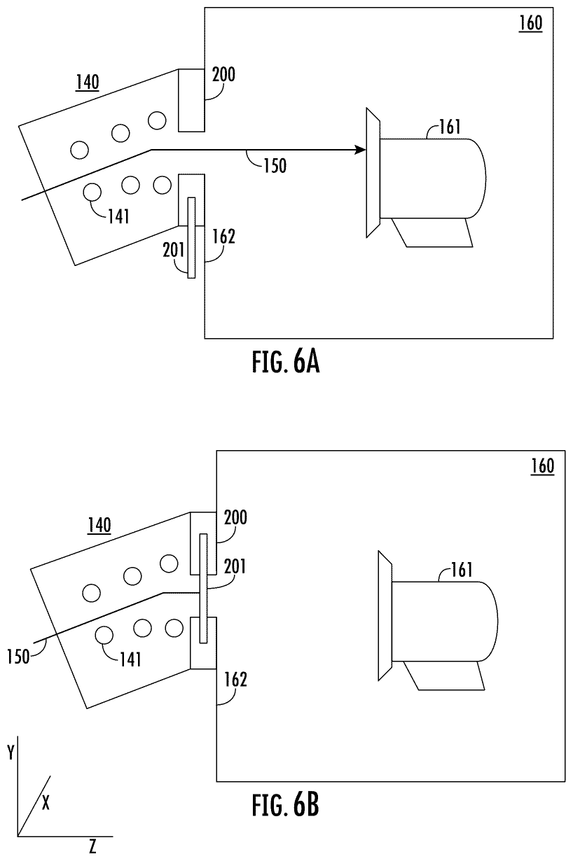

FIGS. 6A-6B show another embodiment. This embodiment is similar to that shown in FIGS. 5A-5B. FIG. 6A shows an open position and FIG. 6B shows a closed position. However, in this embodiment, the movable plate 201 enters from the bottom of the body 202. Thus, to close the isolation valve, the movable plate 201 moves upward. Thus, in this embodiment, the movable plate 201 moves upward from a position that is below the ion beam 150 in a direction parallel to the front wall 162 of the process chamber 160.

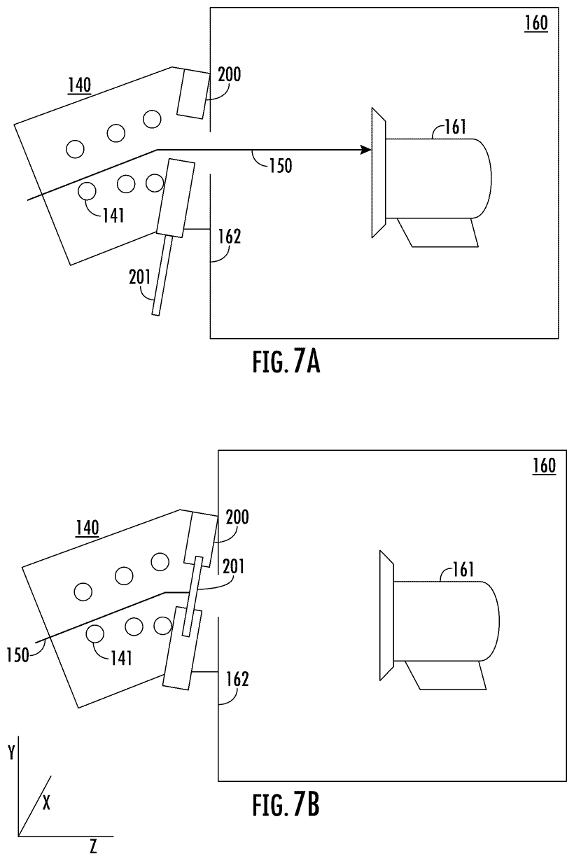

Due to the configuration and interconnection between the acceleration/deceleration stage 140 and the process chamber 160, in some systems, it may be difficult to install the isolation valve 200 in a position where the movable plate 201 travels in a path that is parallel to the front wall 162 of the process chamber. FIGS. 7A-7B show such an embodiment, wherein FIG. 7A shows the isolation valve 200 in the open position and FIG. 7B shows the isolation valve 200 in the closed position. In this embodiment, the isolation valve 200 is installed at an angle relative to the front wall 162 of the process chamber 160. Further, the movable plate 201 moves upward from a position that is below the ion beam 150. As the movable plate 201 moves upward, it draws nearer to the process chamber 160.

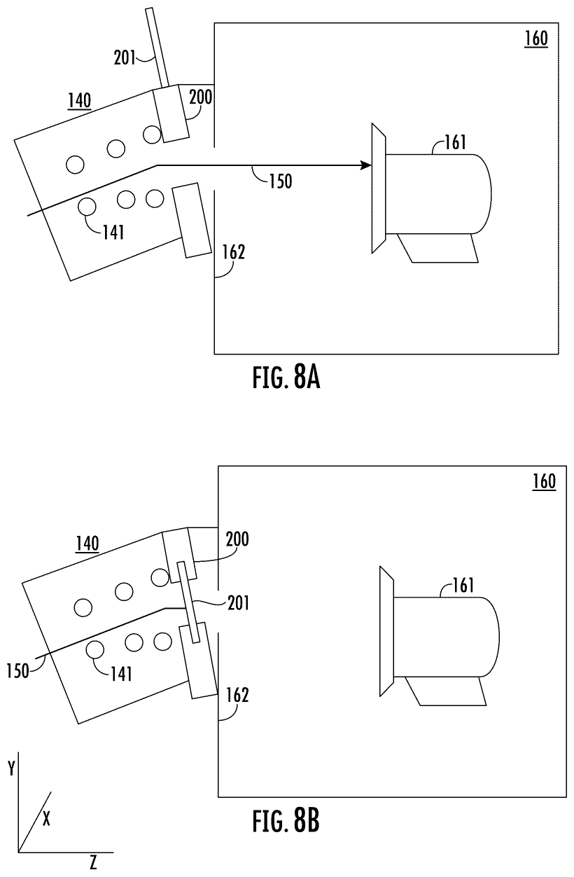

FIGS. 8A-8B shows a second such embodiment, wherein FIG. 8A shows the isolation valve 200 in the open position and FIG. 8B shows the isolation valve 200 in the closed position. In this embodiment, the isolation valve 200 is also installed at an angle relative to the front wall 162 of the process chamber 160. Further, the movable plate 201 moves downward from a position that is above the ion beam 150. As the movable plate 201 moves downward, it draws nearer to the process chamber 160, and reaches the closed position shown in FIG. 8B.

Note that while FIGS. 5A-5B, 6A-6B, 7A-7B and 8A-8B show some of the beam line components being positioned at a height that is lower than the entrance to the process chamber 160, other embodiments are possible. For example, these beam line components may be positioned at a height that is higher than the entrance to the process chamber 160. Note that in each of these embodiments, the isolation valve 200 does not contact any of the biased rods 141 in the electrostatic filter.

Further, as noted above, the last beam line component before the process chamber 160 may be a different component, such as an angle corrector or another component. In all embodiments, the isolation valve is disposed before the process chamber 160, such as between the beam line component immediately upstream from the process chamber 160 and the process chamber 160.

The system described herein has many advantages. In each of these embodiments, it is possible to perform preventative maintenance on the rest of the ion implantation system without venting the process chamber. Additionally, it is possible to perform preventative maintenance on the process chamber without venting the rest of the ion implantation system. During ion implantation, material from the workpiece and other regions in the process chamber may sputter when impacted by the ion beam. This sputtered material may become deposited within the process chamber. For example, silicon, photoresist, oxides, and nitride material from a silicon workpiece may sputter and be deposited on the walls of the process chamber 160. Additionally, some of the sputtered material may travel upstream and be deposited on the rods and surrounding areas, such as the tunnel between acceleration/deceleration stage 140 and the process chamber 160. 160 is vented in anticipation of When the process chamber preventative maintenance, these deposits may become oxidized, forming silicon dioxide and other materials, which may be insulating materials. Further, unexpectedly, it has ben found that these silicon dioxide deposits may detach from the walls of the process chamber 160 and travel upstream, potentially becoming attached to upstream components, such as the rods in the electrostatic filter. Additionally, any silicon or other material used in previous processes, such as phosphorus, carbon and some metals previously sputtered onto the rods may also oxidize and become insulating. When a subsequent ion implantation process is performed, these rods are biased and may glitch, hurting yield and throughput.

By introducing an isolation valve between the process chamber and the electrostatic filter, this isolation valve may be closed while preventative maintenance is performed on the process chamber, eliminating the possibility of contamination upstream from the process chamber. This may reduce the frequency of preventative maintenance of the rest of the ion implantation system. Further, the isolation valve may be configured to be installed into new systems and retrofitted into existing systems without affecting the operation of the ion implantation system.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An ion implantation system comprising:
an ion source to generate an ion beam;
one or more beamline components located downstream from the ion source to guide the ion beam toward a workpiece;
a process chamber, housing a platen; and
an isolation valve disposed between the process chamber and a component of the one or more beamline components located immediately upstream from the process chamber.

2. The ion implantation system of claim 1, wherein the component located immediately upstream from the process chamber comprises an acceleration/deceleration stage.

3. The ion implantation system of claim 2, wherein the acceleration/deceleration stage is an electrostatic filter comprising a plurality of biased rods.

4. The ion implantation system of claim 3, wherein the isolation valve does not contact any of the plurality of biased rods.

5. The ion implantation system of claim 1, wherein the isolation valve comprises a body and a movable plate.

6. The ion implantation system of claim 5, wherein the movable plate descends from a location above the ion beam to isolate the process chamber.

7. The ion implantation system of claim 5, wherein the movable plate moves upward from a location below the ion beam to isolate the process chamber.

8. The ion implantation system of claim 5, wherein the movable plate travels along a path parallel to a front wall of the process chamber.

9. An ion implantation system comprising:
an ion source to generate an ion beam;
one or more beamline components located downstream from the ion source to guide the ion beam toward a workpiece;
a process chamber, housing a platen; and
an isolation valve disposed between the process chamber and a component of the one or more beamline components located immediately upstream from the process chamber, wherein the isolation valve comprises a body and a movable plate and the movable plate travels along a path that is not parallel to a front wall of the process chamber.

10. The ion implantation system of claim 9, wherein the movable plate moves upward from a location below the ion beam to isolate the process chamber.

11. The ion implantation system of claim 10, wherein as the movable plate moves upward, the movable plate draws closer to the process chamber.

12. The ion implantation system of claim 9, wherein the movable plate moves downward from a location above the ion beam to isolate the process chamber.

13. The ion implantation system of claim 12, wherein as the movable plate moves downward, the movable plate draws closer to the process chamber.

14. The ion implantation system of claim 9, wherein the component located immediately upstream from the process chamber comprises an acceleration/deceleration stage.

15. The ion implantation system of claim 14, wherein the acceleration/deceleration stage is an electrostatic filter comprising a plurality of biased rods, and wherein the isolation valve does not contact any of the plurality of biased rods.

16. An ion implantation system comprising:
an ion source to generate an ion beam;
one or more beamline components located downstream from the ion source to guide the ion beam toward a workpiece;
a process chamber, housing a platen; and
an isolation valve disposed between the process chamber and a component of the one or more beamline components located immediately upstream from the process chamber, wherein the isolation valve comprises a body and a movable plate, wherein the movable plate descends from a location above the ion beam to isolate the process chamber.

17. The ion implantation system of claim 16, wherein the movable plate travels along a path parallel to a front wall of the process chamber.

18. The ion implantation system of claim 16, wherein the movable plate travels along a path that is not parallel to a front wall of the process chamber.

19. The ion implantation system of claim 16, wherein the component located immediately upstream from the process chamber comprises an acceleration/deceleration stage.

20. The ion implantation system of claim 19, wherein the acceleration/deceleration stage is an electrostatic filter comprising a plurality of biased rods, and wherein the isolation valve does not contact any of the plurality of biased rods.
